(19) United States
(12) Patent Application Publication
(10) Pub. No.: US 2025/0306780 A1
(43) Pub. Date: Oct. 2, 2025

(54) STORAGE MEMORY DEVICE HAVING MULTI TIME PROGRAMMABLE MEMORY AND OPERATING METHOD THEREOF

(71) Applicant: Samsung Electronics Co., Ltd., Suwon-si (KR)

(72) Inventor: Byungyun Cho, Suwon-si (KR)

(21) Appl. No.: 18/814,749

(22) Filed: Aug. 26, 2024

(30) Foreign Application Priority Data
Apr. 1, 2024 (KR) 10-2024-0043895

(51) Int. Cl. G06F 3/06

(52) U.S. Cl. CPC G06F 3/0625; G06F 3/0634; G06F 3/0656; G06F 3/0679

(57) ABSTRACT

A storage device includes a memory device, at least one non-volatile memory device, a controller controlling the memory device and the at least one non-volatile memory device; and a power management chip supplying power corresponding to the memory device, the at least one non-volatile memory device, and the controller, wherein the power management chip includes a multi-time programmable (MTP) memory storing hardware set data, and the storage device is configured to have an initialization operation performed therefor using the hardware set data, after performing a power-on operation of the storage device.

### CROSS-REFERENCE TO RELATED APPLICATION(S)

This application claims benefit of priority to Korean Patent Application No. 10-2024-0043895 filed on Apr. 1, 2024 in the Korean Intellectual Property Office, the disclosure of which is incorporated herein by reference in its entirety.

### BACKGROUND OF THE INVENTION

The present inventive concept relates to a storage device having a multi-time programmable memory, and a method of operating the same.

Generally, a PMIC (Power Management Integrated Circuit) used in SSD (Solid State Drive) applications may include at least one buck converter, a current limit circuit, a housekeeping block, a voltage level detector, an on-chip voltage regulator, a high-frequency oscillator, a POR (Power on Reset), a reference level detector, and ESD (Electrostatic Discharge) protection circuits. The PMIC may function to generate reference voltages and bias voltages for all other blocks. The output voltage of each buck converter may perform functions such as DVS (Dynamic Voltage Scaling), forced discharge mode, PG (Power Good) feature, and power-off capability using the I2C (Inter-Integrated Circuit) interface. Additionally, the PMIC may include a default voltage setting mode to support changing the default voltage of each output during power-on.

### SUMMARY OF THE INVENTION

An aspect of the present inventive concept is to provide a storage device reducing a hardware setup time period of a power management chip during an initialization operation, and a method of operating the same.

An aspect of the present inventive concept is to provide a storage device simply changing a hardware setting of a power management chip for each product, and a method of operating the same.

According to an aspect of the present inventive concept, a storage device includes a memory device; at least one non-volatile memory device; a controller controlling the memory device and the at least one non-volatile memory device; and a power management chip supplying power corresponding to the memory device, the at least one non-volatile memory device, and the controller, wherein the power management chip includes a multi-time programmable (MTP) memory storing hardware set data, and the storage device is configured to have an initialization operation performed therefor using the hardware set data, after performing a power-on operation of the storage device.

According to an aspect of the present inventive concept, a method of operating a storage device, includes performing a power-on operation of the storage device; entering power gating in response to falling of a power control signal; exiting power gating in response to rising of the power control signal; and performing a power-off operation after the exiting power gating, wherein a hardware setting is performed using set data stored in a multi-time programmable (MTP) memory of a power management chip of the storage device, after the performing the power-on operation.

According to an aspect of the present inventive concept, a method of testing a plurality of storage devices on a test board, includes performing a power-on operation of the plurality of storage devices; applying a power voltage to a multi-time programmable (MTP) write-only pin of the test board; when applying the power voltage, transmitting hardware set data to each of the plurality of storage devices through inter-integrated circuit (I2C) communication; and after performing a test operation of each of the plurality of storage devices, performing a power-off operation of the plurality of storage devices, wherein the hardware set data is stored in an MTP memory of a power management chip of each of the plurality of storage devices.

According to an aspect of the present inventive concept, a method of manufacturing a storage device includes performing a surface mounting process on internal components of the storage device; after performing the surface mounting process, performing an adaptive routing test process; after performing the adaptive routing test process, performing a routing process for the storage device on a test board; and after performing the routing process, performing a process of checking firmware/hardware information of the storage device, wherein the performing an adaptive routing test process includes writing set data to a multi-time programmable (MTP) memory of the storage device for a hardware setting.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a view illustrating a test system according to an embodiment.

FIG. 2 is a view illustrating a storage device according to an embodiment.

FIG. 3 is a flowchart illustrating an operation of manufacturing a storage device according to an embodiment.

FIG. 4 is a view illustrating adaptive routing test items according to an embodiment.

FIG. 5 is a flowchart illustrating a hardware setting operation of a storage device according to an embodiment.

FIG. 6A is a flowchart illustrating a power management operation of a general storage device, and FIG. 6B is a flowchart illustrating a power management operation of a storage device according to an embodiment.

FIG. 7 is a view illustrating MTP data according to an embodiment.

FIG. 8 is a view illustrating a host system according to an embodiment.

FIG. 9 is a view illustrating a power management chip according to an embodiment.

FIG. 10 is a ladder diagram illustrating an operation of a host system according to an embodiment.

### DETAILED DESCRIPTION

Hereinafter, using the drawings, the present inventive concept will be described clearly and in detail so that a person skilled in the art may easily implement the same.

A typical storage device may control the hardware settings required by the product (voltage level, off time, undervoltage settings) via I2C (Inter-Integrated Circuit) from the controller after power-on. At this time, latency may occur due to the command transmission time of the I2C. Additionally, when modifications to the hardware settings for different products are needed, a typical storage device may face significant delay risks in the hardware development of the power management chip.

A storage device according to an embodiment of the present invention may store the initial and low-power mode hardware settings required for each product in advance using the MTP (Multi-Time Programmable) memory of the power management chip during the initial test phase of the product production process (SMT-Initial Test-Aging Test-LI). When circuit changes occur, leading to hardware modifications, this storage device may modify the hardware settings through software adjustments without changing the circuit diagram. The storage device of the present invention may reduce the latency of the initialization operation by skipping the I2C control required for hardware settings.

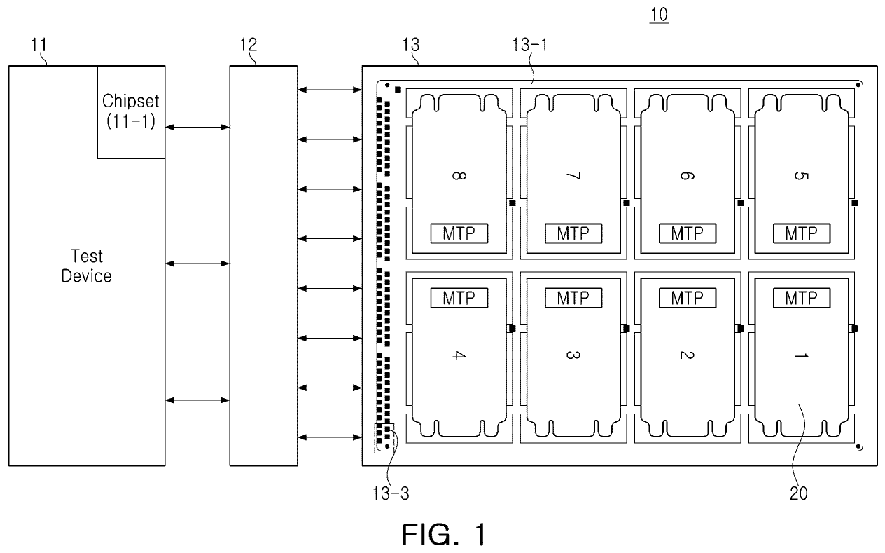

FIG. 1 is a view illustrating a test system according to an embodiment. Referring to FIG. 1, a test system 10 may include a test device 11, a contact module 12, and a test board 13.

The test device 11 may be implemented to perform various operations required for an operation of the test system 10. For example, the test device 11 may interpret a command input from a user, and may perform an operational task (e.g., an operation) or may process data based on the interpreted command. The test device 11 may be referred to as a manufacturing tool/facility for storage devices.

A chipset 11-1 may include a device controlling various types of hardware included in the test system 10 according to a command from the test device 11. For example, the chipset 11-1 may test an operation of a storage device 20 through a test terminal 13-3 according to a command from the test device 11. In an embodiment, an I2C CLK/12C DAT/MTP_Write Pad (13-3) may be allocated in a printed circuit board (PCB) design on/in which storage devices are serially arranged. The I2C CLK may be a clock pin that transfers and receives a clock corresponding to an I2C interface. The I2C DAT may be a data pin that transfers and receives data corresponding to the I2C interface.

The test board 13 may be implemented to exchange a signal with the test device 11, and receive power through the contact module 12. The test board 13 may include a support 13-1 and the test terminal 13-2. A plurality of storage devices 20 may be arranged on the test board 13. Each of the storage devices 20 may be connected to the test board 13 and the support 13-1. The test terminal 13-2 may be connected to a signal line that may electrically inspect each of the storage devices 20 mounted on the test board 13. The support 13-1 may be provided with the test terminal 13-2 on a surface thereof. Therefore, the test terminal 13-2 may be connected to the contact module 12 to execute defect analysis for each of the storage devices 20.

Additionally, the test board 13 may further include an MTP-specific test terminal 13-3. The test terminal 13-3 may include an I2C CLK terminal, an I2C DAT terminal, and an MTP write (e.g., write-only) pad terminal. A data writing operation may be permitted or prohibited to the MTP memory of each of the storage devices 20, depending on a voltage applied to the MTP write pad terminal. For example, when a power voltage is applied to the MTP write pad terminal, an MTP write operation may be permitted. When a voltage of the MTP write pad terminal is a ground voltage, the MTP write operation may be inhibited/prohibited.

In FIG. 1, the storage devices 20 are illustrated as 8 storage devices that are serially arranged (e.g., in two rows) and each have an M.2 specification, and it should be understood that the number of storage devices 20 arranged on the test board 13 is not limited thereto. When analyzing defects for each of the storage devices 20, defect analysis time may be saved because there is no need to separately connect the plurality of storage devices 20 to the test device 11. After the test is completed, when portions connecting each of the storage devices 20 and the support 13-1 are separated, each of the storage devices 20 is provided as a storage device having an M.2 specification.

Each of the storage devices 20 may include a multi-time programmable (MTP) memory. The MTP memory may be implemented as various types of non-volatile memory. Hardware setting(s) may be stored in the MTP memory during a test operation (e.g., a test operation in a manufacturing stage) of each of the storage devices 20.

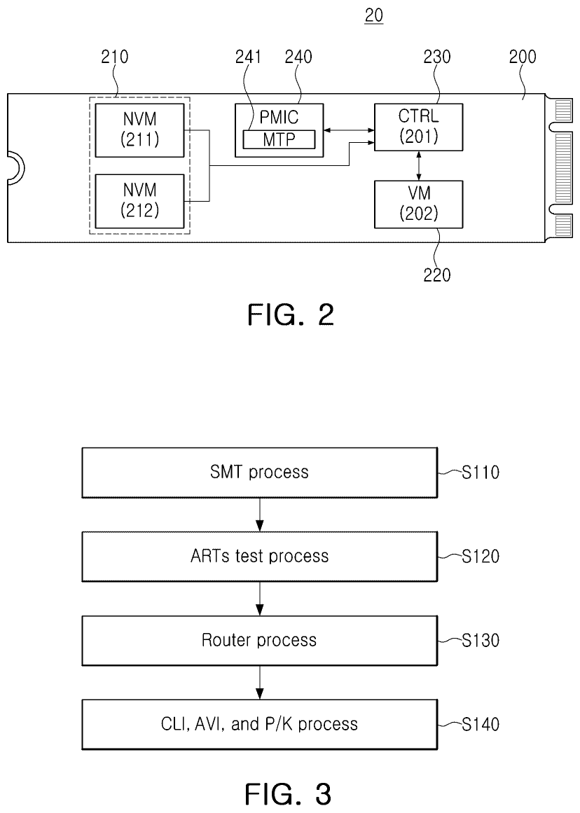

FIG. 2 is a view illustrating a storage device 20 according to an embodiment. As illustrated in FIG. 2, a storage device 20 may have a form factor having an M.2 specification, and may include a printed circuit board 200 on which various types of hardware are mounted. In an embodiment, the form factor having an M.2 specification may define the printed circuit board 200 with a length in a first direction as 22 millimeters (mm) and a length in a second direction as 60 mm, 80 mm, or 110 mm.

As a size of an electronic product including the storage device 20 gradually decreases and the storage device 20 is required to operate at a high speed, a storage device 20 having a size, smaller than a conventional size, and supporting an interface protocol at a high speed is being requested. Therefore, as a form factor corresponding to a relatively small size, for example, an mSATA specification using a PCI Express Mini Card layout, an M.2 specification defining a more flexible size than the mSATA specification, or the like is being proposed.

As illustrated, the M.2 specification may define a small-sized solid-state drive, and the small-sized storage device may include at least one non-volatile memory device 210 mounted on the printed circuit board 200. The M.2 specification may define a port. In an embodiment, the port may be located on one side of the printed circuit board 200, and may include a plurality of pins for communicating with a host device. The plurality of pins may be exposed patterns, and may include a conductive material such as copper (Cu). Additionally, the M.2 specification may specify an indentation structure for mounting and fixing the storage device 20 to a motherboard (or mainboard). The M.2 specification may include a semicircular indentation structure formed on the other side opposite to the port. The exposed patterns may be formed on an edge of the indentation structure, and, when mounted on the motherboard, may be connected to a conductor on the motherboard. For example, the patterns formed on the edge of the indentation structure may be connected to a conductor corresponding to a ground node on the motherboard.

Referring to FIG. 2, the storage device 20 may include at least one non-volatile memory device 210, a memory device 220, a controller 230 (or 201), and a power management chip (PMIC) 240. The controller 230 may be implemented to control first and second non-volatile memory devices 211 and 212 of the non-volatile memory device 210 according to a command from a host device (e.g., the test device in FIG. 1). For example, the controller 230 may read data stored in the first and second non-volatile memory devices 211 and 212 or may program data in the first and second non-volatile memory devices 211 and 212 according to a command from a host device. The memory device 220 may be implemented as a volatile memory 202. In an embodiment, the memory device 220 may be mounted on the printed circuit board 200, and may be electrically connected to the controller 230 through wirings provided on the printed circuit board 200.

The power management chip 240 may be implemented to supply power to the storage device 20, based on power supplied externally. In an embodiment, the power management chip 240 may supply power to the controller 230. The power management chip 240 may include an MTP memory 241. In this case, the MTP memory 241 may store a setting value for a hardware setting of the power management chip 240. In FIG. 2, the MTP memory is illustrated as an internal component of the power management chip 240. The present inventive concept is not limited thereto. The MTP memory may also be implemented as an independent component outside of the power management chip.

FIG. 3 is a flowchart illustrating an operation of manufacturing a storage device according to an embodiment. Referring to FIG. 3, an operation of manufacturing a storage device of the present inventive concept may proceed as follows. A surface mount technology (SMT) process may be performed (S110). Components of a storage device (e.g., 210, 220, 230, and 240) may be mounted on a printed circuit board (e.g., 200 in FIG. 2) by the SMT process. An adaptive routing tests (ARTs) process may be performed (S120). The ARTs process may be a firmware download and product testing process, after assembly. In this case, a hardware setting value may be written to an MTP memory of the storage device. For example, the hardware setting value may be transmitted to the MTP memory of the storage device through an MTP-specific test terminal 13-3 of a test board 13, as illustrated in FIG. 1. In this case, a test device 11 may transfer the hardware setting value to the storage device according to an I2C interface method. Set data may be written to the MTP memory by transmitting the set data to the storage device connected to the test board 13 through I2C communication. It should be understood that a hardware setting value transmission method is not limited to the I2C interface method. A router (e.g., routing) process may be performed (S130). The router process may be a process of cutting a serially arranged PCB (frame for mass assembly of storage devices) into an individual SSD after performing a test operation for the storage device (e.g., for a serially-arranged group of storage devices). A CLI+AVI+P/K process may be performed (S140). A casing-label-interface (CLI) process may be a pre-shipment testing process that verifies (e.g., checks) firmware/hardware information in a product. An auto-visual inspection (AVI) process may be an exterior (e.g., external) inspection process. A packaging (P/K) process may be a packaging process.

An operation of manufacturing a storage device according to an embodiment may be to add I2C CLK/12C DAT and a pad for MTP Write of a PMIC to be assigned to a test pad below in the serially arranged board. Afterwards, after SMT in the assembly process is completed, in the ARTs process, which may be a test stage for FW download and test, a hardware setting for each product may be performed (e.g., provided) by adding a process of writing the hardware setting using a PMIC in which MTP is mounted.

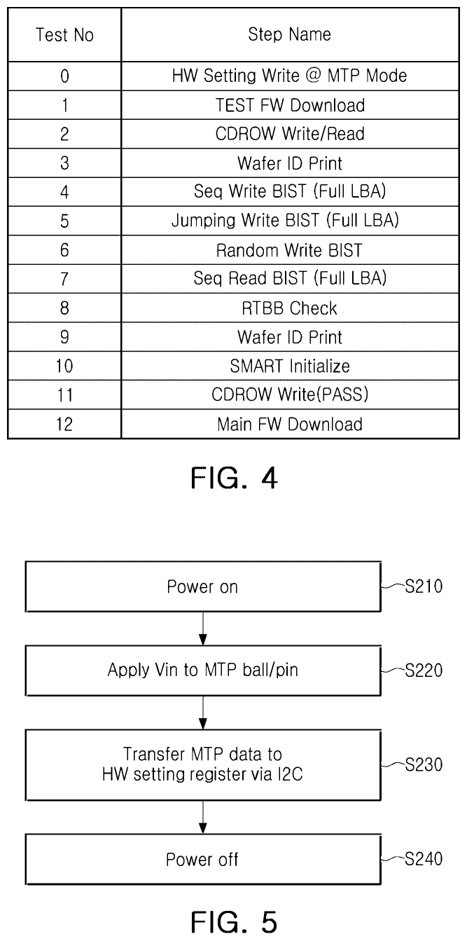

FIG. 4 is a view illustrating adaptive routing test items according to an embodiment. The test items may include Hardware Setting Write in an MTP mode, Test Firmware Download, CDROW Write/Read, Wafer ID Print, Seq Write built-in-self-test (BIST) (Full LBA), Jumping Write BIST (Full LBA), Random Write BIST, Seq Read BIST (Full LBA), RTBB Check, Wafer ID Print, SMART Initialize, CDROW Write (PASS), Main Firmware Download, or the like.

FIG. 5 is a view illustrating a hardware setting operation of a storage device 20 according to an embodiment. Referring to FIGS. 1 to 5, hardware setting of a storage device 20 may proceed as follows. A test device 11 may be powered on (S210). The test device 11 may apply an input voltage (Vin) to an MTP pad terminal (ball/pin) of a test board 13 for the hardware setting of the storage device 20 (S220). In this case, the Vin indicates that a write operation is allowed to the MTP memory of the storage device 20. The test device 11 may transfer MTP data to a hardware setting register of the storage device 20 through an I2C interface (S230). The MTP data may be written to an MTP memory. Afterwards, the test device 11 may be powered off (S240).

In general, power gating in a PMIC may be a process of controlling power to optimize power consumption. A main function thereof may be to transfer power from a source to a load. To do this efficiently, the PMIC may use several technologies. The PMIC may be designed to reduce (e.g., minimize) a loss in power transfer from the source to the load. The PMIC may generate and manage various voltages, depending on power requirements. This may be useful when the load has different power consumption requirements. The PMIC may convert an input voltage to a voltage required by the load. This conversion may facilitate optimizing power consumption and increasing efficiency. The PMIC may include a smart control algorithm that may dynamically adjust power supply according to given conditions. This may facilitate maintaining optimal performance, as the power requirements change. The PMIC may switch to a low power mode (rather than a standard/active/high-power mode), when the load does not operate, to minimize energy consumption. The PMIC may monitor a temperature and a voltage to maintain the stability of the power supply. This may facilitate detecting and preventing potential problems early. These features allow the PMIC to optimize power consumption and perform effectively power management of a device.

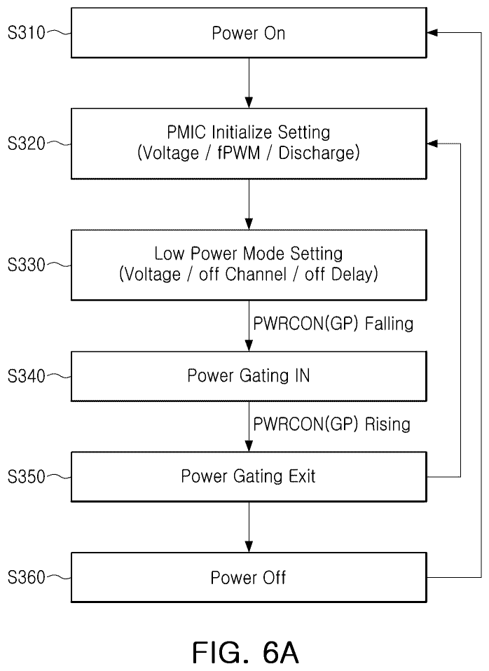

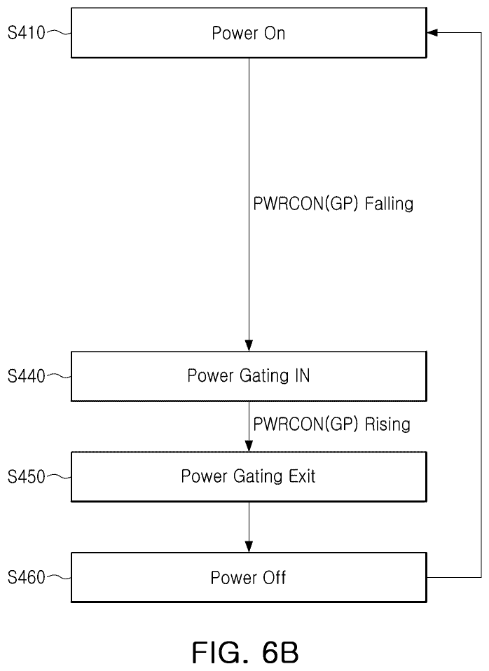

FIG. 6A is a view illustrating a power management operation of a general storage device, and FIG. 6B is a view illustrating a power management operation of a storage device according to an embodiment.

Referring to FIG. 6A, a power management operation of a general storage device may proceed as follows. A storage device may be powered on (S310). Through I2C communication, an initialization setting (Voltage/fPWM/Discharge) operation of a power management integrated circuit (PMIC) of the storage device may be performed (S320). A power mode setting (voltage/off channel/off delay) operation may be performed through the I2C communication (S330). In some embodiments, the power mode setting operation may be a low power mode setting operation that uses (e.g., rewrites) hardware set data in response to a low power mode request from an external device (e.g., a host device). A power gating operation (e.g., power gating of/by the PMIC) may be entered in response to falling (i.e., decreasing) of a power control signal (PWRCON (GP)) (S340). The power gating operation may be exited in response to rising of the power control signal (PWRCON (GP)) (S350). Afterwards, the storage device may be powered off (S360). The PMIC may enter or exit a low power mode in response to a power control signal without (i.e., independently of) a command according to I2C communication.

Referring to FIG. 6B, a power management operation of a storage device of the present inventive concept may proceed as follows. A storage device may be powered on (S410). The storage device may execute a hardware setting using set data of an MTP memory, after the storage device is powered on. A power gating operation may be entered in response to falling of a power control signal (PWRCON (GP)) (S440). The power gating operation may be exited in response to rising of the power control signal (PWRCON (GP)) (S450). Afterwards, the storage device may be powered off (S460).

A storage device according to an embodiment may reflect a HW setting item through PMIC MTP Write in an assembly (e.g., manufacturing) stage. Through this, when initializing the storage device, hardware setting through I2C communication (e.g., S320 and S330 in FIG. 6A) may be skipped. In addition, a storage device according to an embodiment may operate only by controlling a PWRCON (GP) signal when entering/exiting a low power mode with a Masking+Standby Mode function. As a result, a storage device of the present inventive concept may reduce latency of an initialization operation and reduce (e.g., eliminate) risk of communication errors.

A storage device according to an embodiment may reduce operation latency by skipping a time required for a hardware setting, after power-on of a product. A storage device according to an embodiment may reduce (e.g., minimize) failure of I2C communication. A storage device according to an embodiment may reduce (e.g., minimize) hardware revision. In a storage device according to an embodiment, PMIC mode pin (M0/M1/M2/M3, VSLT) Ball may be deleted. A storage device according to an embodiment may reduce a size of a PMIC package, and may increase a degree of freedom in board design.

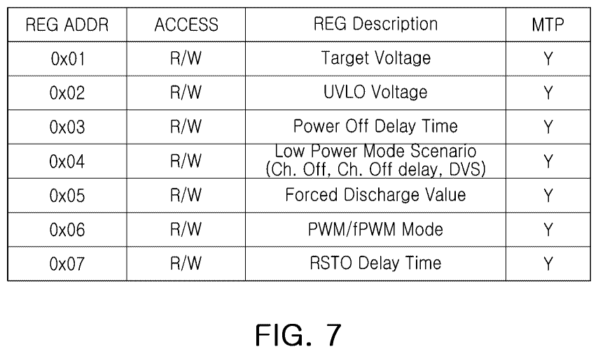

FIG. 7 is a view illustrating MTP data according to an embodiment. As illustrated in FIG. 7, MTP data may include a target voltage, an undervoltage lockout (UVLO) voltage, a power off delay time, a low power mode scenario (Ch. Off, Ch. Off delay, (DVS)), a forced discharge value, a pulse width modulation (PWM)/forced PWM (fPWM) mode, and a soft turn off resistor (RSTO) delay time. In this case, the target voltage may be a product required voltage control factor for the storage device. The undervoltage lockout (UVLO) voltage may be an on/off sequence control factor. The power off delay time may be an on/off sequence control factor. The low power mode scenario (Ch. Off, Ch. Off delay, DVS) may be an L1.2 control factor. The forced discharge value may be an off time control factor. The pulse width modulation (PWM)/forced PWM (fPWM) mode may be a ripple control factor. The soft turn off resistor (RSTO) delay time may be a controller reset time control factor.

The present inventive concept may be applicable to various host systems.

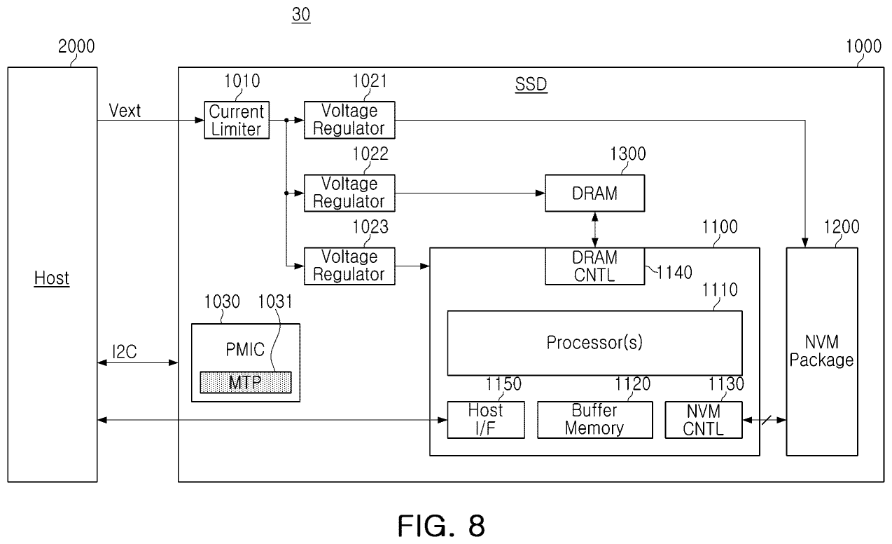

FIG. 8 is a view illustrating a host system 30 according to an embodiment. Referring to FIG. 8, a host system 30 may include a storage device (SSD) 1000 and a host device 2000. As illustrated in FIG. 8, the storage device (SSD) 1000 may include a current limiter 1010, voltage regulators 1021, 1022, and 1023, a PMIC 1030, a controller 1100, a non-volatile memory package 1200, and a volatile memory device (DRAM) 1300.

The current limiter 1010 may be implemented to receive an external voltage Vext from the host device 2000 and limit an input current. Each of the voltage regulators 1021, 1022, and 1023 may be implemented to generate voltages necessary for the adjacent devices (1100, 1200, and 1300) corresponding (and coupled) thereto in the storage device 1000, and provide generated voltages.

The PMIC 1030 may be implemented to manage power of the storage device 1000. The PMIC 1030 may include an MTP memory 1031 storing a hardware setting value. In FIG. 8, the current limiter 1010 and the voltage regulators 1021, 1022, and 1023 are illustrated as being separated from the PMIC 1030, but it should be understood that the present inventive concept is not limited thereto. The current limiter 1010 and the voltage regulators 1021, 1022, and 1023 may be implemented to include the current limiter 1010 and the voltage regulators 1021, 1022, and 1023.

The controller 1100 may be implemented to control an overall operation of the storage device 1000. The controller 1100 may include at least one processor (central processing unit (CPU)) 1110, a buffer memory 1120, a non-volatile memory controller 1130, a volatile memory (e.g., DRAM) controller 1140, and a host interface circuit 1150. Moreover, the controller 1100 may, in some embodiments, include a voltage controller.

The at least one processor 1110 may be implemented to control an overall operation of the controller 1100. The processor 1110 may be implemented to drive a direct memory access (DMA) engine. In this case, the DMA engine may control a direct memory access (DMA) operation of the storage device 1000. The DMA engine may perform data transmission with a host device or a different external device under control of the processor 1110. For example, the DMA engine may transfer read data loaded into the volatile memory device 1300 in/as a stream form to the host device 2000 in a DMA transfer mode.

Alternatively, the DMA engine may store stream data provided from the host device 2000 in the volatile memory device 1300 in the DMA transfer mode. In practice, the DMA engine may perform direct memory access (DMA) operations of the host device 2000 and the volatile memory device 1300.

The buffer memory 1120 may be implemented to temporarily store data required for an operation of the controller 1100. The buffer memory 1120 may be implemented as a volatile memory (e.g., a static random access memory (SRAM), a dynamic RAM (DRAM), a synchronous DRAM (SDRAM), or the like) or a non-volatile memory (a flash memory, a phase-change RAM (PRAM), a magneto-resistive RAM (MRAM), a resistive RAM (ReRAM), a ferro-electric RAM (FRAM), or the like).

The non-volatile memory controller 1130 may be implemented to control the non-volatile memory package 1200. The non-volatile memory controller 1130 may perform various management operations such as cache/buffer management, firmware management, garbage collection management, wear leveling management, data deduplication management, read refresh/reclaim management, bad block management, multi-stream management, mapping management of host data and non-volatile memory, quality-of-service (QOS) management, system resource allocation management, non-volatile memory queue management, read level management, erase/program management, hot/cold data management, power loss protection management, dynamic thermal management, initialization management, redundant array of independent/inexpensive disks (RAID) management, or the like.

The non-volatile memory controller 1130 may transfer a command and an address to perform a program operation, a read operation, an erase operation, or the like in a non-volatile memory device of the non-volatile memory package 1200. The non-volatile memory controller 1130 may be connected to the non-volatile memory package 1200 through a plurality of control pins transmitting control signals (e.g., command latch enable (CLE), address latch enable (ALE), chip enable(s) (CE(s)), write enable (WE), read enable (RE), or the like). Additionally, the non-volatile memory package 1200 may be controlled using control signals (CLE, ALE, CE(s), WE, RE, or the like). In an embodiment, the non-volatile memory controller 1130 may be implemented to comply with a standard protocol such as a joint electron device engineering council (JEDEC) toggle or an open NAND flash interface (ONFI).

Additionally, the non-volatile memory controller 1130 may include an error correction code (ECC) circuit. The ECC circuit may generate an error correction code to correct a fail bit or an error bit of data received from the non-volatile memory package 1200. The ECC circuit may perform error correction encoding of data provided in the non-volatile memory package 1200, to form data to which a parity bit is added. The parity bit may be stored in the non-volatile memory package 1200. Additionally, the ECC circuit may perform error correction decoding on data output from the non-volatile memory package 1200. The ECC circuit may correct errors using parity. The ECC circuit may correct errors using coded modulation, such as a low density parity check (LDPC) code, a BCH code, a turbo code, a Reed-Solomon code, a convolution code, a recursive systematic code (RSC), a Trellis-coded modulation (TCM), block coded modulation (BCM), or the like. When error correction is not possible in the ECC circuit, a read retry operation may be performed.

Additionally, non-volatile memory controller 1130 may include a flash translation layer manager. The flash translation layer manager may perform several functions such as address mapping, wear-leveling, or garbage collection. Also, the non-volatile memory controller 1130 may include a security module. The security module may perform at least one of an encryption operation or a decryption operation on data input to the processor 1110 using a symmetric-key algorithm. The security module may include an encryption module and a decryption module. In an embodiment, the security module may be implemented in terms of hardware/software/firmware. The security module may be implemented to perform security functions of the storage device 1000. For example, the security module may perform a self-encryption disk (SED) function or a trusted computing group (TCG) security function.

The SED function may store encrypted data in the non-volatile memory device 210 (FIG. 2) (e.g., in the non-volatile memory package 1200) using an encryption algorithm, or may decrypt the encrypted data from the non-volatile memory device 210. Such encryption/decryption operations may be performed using an encryption key, internally generated. In an embodiment, the encryption algorithm may be an advanced encryption standard (AES) encryption algorithm. It should be understood that the encryption algorithm is not limited thereto. The TCG security function may provide a mechanism enabling access control to user data in the storage device 1000. For example, the TCG security function may perform an authentication procedure between the external device and the storage device 1000. In an embodiment, the SED function or the TCG security function may be optionally selected. In addition, the security module may be implemented to perform an authentication operation with the external device or a fully homomorphic encryption function.

The volatile memory controller 1140 may be implemented to control the volatile memory device 1300. The volatile memory controller 1140 may write data to the volatile memory device 1300 or read data stored in the volatile memory device 1300 under control of the processor 1110. In this case, the volatile memory controller 1140 may include a buffer allocation unit for managing the volatile memory device 1300 as a buffer. The buffer allocation unit may manage use and release of the volatile memory device 1300.

The host interface circuit 1150 may be implemented to communicate with the host device 2000. The host interface circuit 1150 may be implemented to transfer and receive a packet to and from the host device 2000. The packet transmitted from the host device 2000 to the host interface circuit 1150 may include a command, or data to be written to the non-volatile memory package 1200. The packet transmitted from the host interface circuit 1150 to the host device 2000 may include a response to a command, or data to be read from the non-volatile memory package 1200. In an embodiment, the host interface circuit 1150 may be interchangeable with at least one of a peripheral component interconnect express (PCIe) interface standard, a universal serial bus (USB) interface standard, a compact flash (CF) interface standard, a multi-media card (MMC) interface standard, an embedded MMC (eMMC) interface standard, a thunderbolt interface standard, a universal flash storage (UFS) interface standard, a secure digital (SD) interface standard, a memory stick interface standard, an extreme digital (xD)-picture card interface standard, an integrated drive electronics (IDE) interface standard, a serial advanced technology attachment (SATA) interface standard, a small computer system interface (SCSI) interface standard, a serial attached SCSI (SAS) interface standard, or an enhanced small disk interface (ESDI) interface standard.

The non-volatile memory package 1200 may include at least one non-volatile memory device. In this case, the non-volatile memory device may be implemented as a three-dimensional array structure. For example, the non-volatile memory device may be implemented as a vertical non-volatile memory device. The non-volatile memory package 1200 may be connected to the non-volatile memory controller 1130 through at least one channel. In this case, a plurality of non-volatile memory devices may be connected to the at least one channel. Each of the non-volatile memory devices may include a plurality of memory cells connected to word lines and bit lines. In this case, each of the plurality of memory cells may be implemented to store at least one bit.

The volatile memory device 1300 may be used as a data buffer for exchanging data between the storage device 1000 and the host device 2000. Additionally, the volatile memory device 1300 may store a mapping table for mapping a logical address provided to the storage device 1000 and an address of the non-volatile memory package 1200. The mapping table may be loaded from the non-volatile memory package 1200 to the volatile memory device 1300 during an initialization operation of (e.g., performed by and/or for) the storage device 1000. The volatile memory device 1300 may temporarily store write data provided from the host device 2000 or data read from the non-volatile memory package 1200. When data existing in the non-volatile memory package 1200 is cached upon a read request from the host device 2000, the volatile memory device 1300 may support a cache function directly providing the cached data to the host device 2000. In an embodiment, the volatile memory device 1300 may be implemented with a dynamic random access memory (DRAM) to provide sufficient buffering in the storage device 1000.

The host device 2000 may communicate with the storage device 1000 according to a first communication interface or a second communication interface. In this case, the first communication interface may be a host interface. The second interface may be a side-channel interface. The side channel interface may be, for example, an I2C interface.

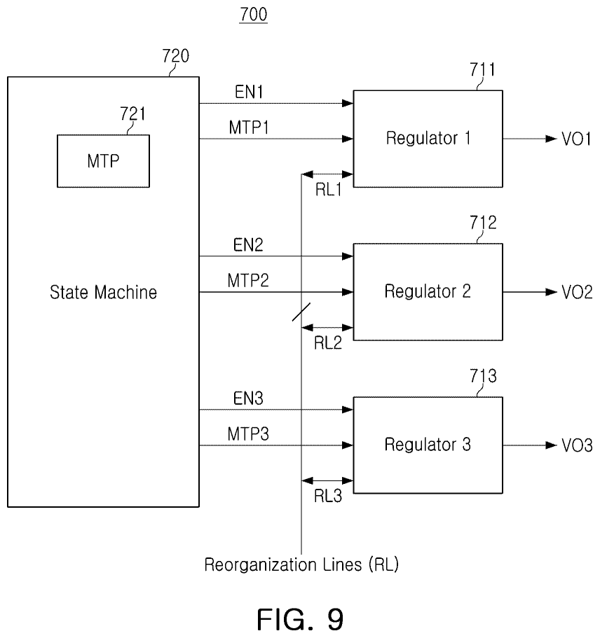

FIG. 9 is a view illustrating a power management chip 700 according to an embodiment. Referring to FIG. 9, a power management chip 700 may include regulators 711, 712, and 713 and a state machine 720.

A first regulator 711 may be implemented to receive a first setting value MTP1 and a first activation signal EN1 from the state machine 720 and output a first voltage VO1. A second regulator 712 may be implemented to receive a second setting value MTP2 and a second activation signal EN2 from the state machine 720 and output a second voltage VO2. A third regulator 713 may be implemented to receive a third setting value MTP3 and a third activation signal EN3 from the state machine 720 and output a third voltage VO3. As illustrated in FIG. 9, the regulators 711, 712, and 713 may receive the activation signals (EN1/EN2/EN3) controlling an on/off state, and may receive the setting values (MTP1/MTP2/MTP3) for selectively using an internal function, respectively.

The state machine 720 may be implemented to control the regulators 711, 712, and 713. The state machine 720 may include an MTP 721. The MTP 721 may store the setting values (MTP1, MTP2, MTP3). Additionally, the plurality of regulators 711, 712, and 713 may receive reorganization line values RL1, RL2, and RL3 selecting a reorganization line RL from the state machine 720 for parallel configuration. In general, the reorganization line values RL1, RL2, and RL3 may be MTP values. In this case, the reorganization line RL may be a line physically connecting information necessary for parallel configuration of the regulators 711, 712, and 713 in a chip. Load current detection signals and clock signals may be mainly transmitted through the reorganization line RL. Additionally, a setting value of the MTP 721 may be changed during a product test operation or a real-time operation.

The present inventive concept may also be implemented to set an optimal operating mode in real time.

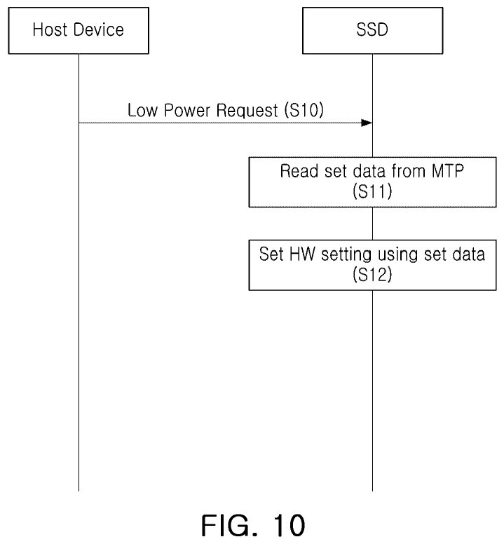

FIG. 10 is a ladder diagram illustrating an operation of a host system according to an embodiment. Referring to FIG. 10, a host system may enter a low power mode as follows. A host device (which may be an external device) may transfer a low power mode request to a storage device (SSD) according to a request of a user or internal policy (S10). The storage device (SSD) may read set data, corresponding thereto, from an MTP memory in response to the low power mode request (S11). The storage device (SSD) may perform (e.g., provide/implement) a hardware setting corresponding to a low power mode using the read set data (S12). In an embodiment, the set data may be stored during a process of manufacturing (e.g., during a manufacturing stage of) the storage device. In some embodiments, the set data may be changed (e.g., rewritten) during an operation of the storage device.

The device described above may be implemented with a hardware component, a software component, and/or a combination of the hardware component and the software component. For example, the devices and the components, described in an embodiment, may be implemented using one or more general-purpose or special-purpose computers, such as a processor, a controller, an arithmetic logic unit (ALU), a digital signal processor, a microcomputer, a field programmable gate array (FPGA), a programmable logic unit (PLU), a microprocessor, or any other device capable of executing and responding to an instruction. A processing device may execute an operating system (OS), and one or more software applications running on the operating system. Additionally, the processing device may access, store, manipulate, process, and generate data in response to execution of software. For ease of understanding, a single processing device is described as being used; however, those skilled in the art will understand that a processing device may include multiple processing elements or multiple types of processing elements. For example, a processing device may include a plurality of processors or one processor, and one controller. Additionally, other processing configurations, such as parallel processors, are possible.

Software may include computer programs, code, instructions, or any combination thereof, and may configure a processing device to operate as desired or may independently or collectively instruct the processing device. Software and/or data may be embodied in any type of machine, component, physical device, virtual device, computer storage medium, or device, in order to be interpreted by or to provide instructions or data to a processing device. Software may be distributed and stored or executed in a distributed manner on a network-connected computer system. Software and data may be stored on one or more computer-readable recording media.

A storage device according to an embodiment of the present invention may be implemented with a structure where I2C clock (CLK)/12C data (DAT)/MTP Write (e.g., MTP write-only) Pads (e.g., pins, terminals of the PMIC 1030) are allocated to the Test Pad in the SSD rear-array PCB for MTP Write. In this embodiment, an SSD process that adds a step of writing HW settings for each SSD product using MTP may be introduced. Previously, an increase in latency due to PMIC Initialize Setting and Low Power Mode Setting via communication control (I2C) after Power On was necessary. However, after pre-HW setting through PMIC MTP, the additional HW setting step via I2C after Power On may be skipped, thereby reducing latency.

Furthermore, the existing SSD HW modification items (e.g., voltage, sequence, etc.) may be changed in terms of HW specifications (voltage, UVLO, RESETB, etc.) via software using PMIC MTP, thus reducing HW revision risk. Additionally, while the PMIC HW remains the same, the need for material dualization management based on setting values is reduced/eliminated. Moreover, the number of PMIC allocated balls can be reduced, thereby allowing a reduction in PKG size and increasing the flexibility of PCB design. For example, the balls that can be deleted may include M0, M1, M2, M3, and VSLT. A storage device and a method of operating the same, according to an embodiment, may reduce a hardware setup time period of a power management chip by using MTP.

A storage device and a method of operating the same, according to an embodiment, may simplify hardware setting of a power management chip by storing product-specific hardware set data in MTP in a test stage.

A storage device and a method of operating the same, according to an embodiment, may reduce latency by skipping side-channel communication control required for a hardware setting.

While example embodiments have been illustrated and described above. it will be apparent to those skilled in the art that modifications and variations could be made without departing from the scope of the present inventive concept as defined by the appended claims.

1. A storage device comprising:
a memory device;
at least one non-volatile memory device;
a controller configured to control the memory device and the at least one non-volatile memory device; and
a power management chip configured to supply power voltages corresponding to the memory device, the at least one non-volatile memory device, and the controller,
wherein the power management chip includes a multi-time programmable (MTP) memory storing hardware set data, and
wherein the storage device is configured to have an initialization operation performed therefor using the hardware set data, after performing a power-on operation of the storage device.

2. The storage device of claim 1, wherein the MTP memory is configured to store the hardware set data during a test operation in a manufacturing stage of the storage device.

3. The storage device of claim 1, wherein the storage device is configured to have a low power mode setting operation performed therefor using the hardware set data in response to a low power mode request from an external device.

4. The storage device of claim 1, wherein the storage device is configured to have at least one of a target voltage, an undervoltage lockout (UVLO) level, or a power on/off scenario changed using the hardware set data.

5. The storage device of claim 1, wherein the hardware set data comprises a target voltage, an undervoltage lockout (UVLO) voltage, a power off delay time, a low power mode scenario, a forced discharge value, a pulse width modulation (PWM)/forced PWM (fPWM) mode, or a soft turn off resistor (RSTO) delay time.

6. The storage device of claim 1, wherein the power management chip comprises an MTP write-only pin, a clock pin, and a data pin.

7. The storage device of claim 6, wherein the clock pin and the data pin are configured to transfer and receive a clock and data, respectively, corresponding to an inter-integrated circuit (I2C) interface.

8. The storage device of claim 1, wherein the power management chip is configured to enter or exit a low power mode in response to a power control signal without a command according to inter-integrated circuit (I2C) communication.

9. The storage device of claim 8,
wherein the power management chip is configured to enter power gating in response to falling of the power control signal, and
wherein the power management chip is configured to exit power gating in response to rising of the power control signal.

10. The storage device of claim 1, wherein the storage device has a form factor having an M.2 specification.

11. A method of operating a storage device, the method comprising:
performing a power-on operation of the storage device;
entering power gating in response to falling of a power control signal;
exiting power gating in response to rising of the power control signal; and
performing a power-off operation after the exiting power gating,
wherein a hardware setting is performed using set data stored in a multi-time programmable (MTP) memory of a power management chip of the storage device, after the performing the power-on operation.

12. The method of claim 11, further comprising writing the set data to the MTP memory in a testing stage of the storage device.

13. The method of claim 12, wherein the writing the set data to the MTP memory comprises transmitting the set data to the storage device connected to a test board through inter-integrated circuit (I2C) communication.

14. The method of claim 13,
wherein the test board comprises an MTP write-only terminal, and
wherein a write operation of the MTP memory is allowed or prohibited, depending on a voltage applied to the MTP write-only terminal.

15. The method of claim 11, further comprising
receiving a low power mode request from an external device; and
reading set data from the MTP memory in response to the low power mode request; and
setting the power management chip according to the set data.

16. A method of testing a plurality of storage devices on a test board, the method comprising:
performing a power-on operation of the plurality of storage devices;
applying a power voltage to a multi-time programmable (MTP) write-only pin of the test board;
when applying the power voltage, transmitting hardware set data to each of the plurality of storage devices through inter-integrated circuit (I2C) communication; and
after performing a test operation of each of the plurality of storage devices, performing a power-off operation of the plurality of storage devices,
wherein the hardware set data is stored in an MTP memory of a power management chip of each of the plurality of storage devices.

17. The method of claim 16, wherein, when a ground voltage is applied to the MTP write-only pin, a write operation on the MTP memory is prohibited.

18. The method of claim 16, wherein the test board comprises a printed circuit board (PCB) having the plurality of storage devices serially arranged thereon.

19. The method of claim 18, wherein, after the test operation, an individual storage device among the plurality of storage devices is cut from the PCB.

20. The method of claim 16, wherein each of the plurality of storage devices rewrites the hardware set data stored in the MTP memory in response to a low power mode request.

21-25. (canceled)
